(19) United States
(12) Patent Application Publication
(10) Pub. No.: US 2025/0316600 A1
(43) Pub. Date: Oct. 9, 2025

(54) ELECTRONIC DEVICE AND METHOD FOR MANUFACTURING THE SAME

(71) Applicant: Innolux Corporation, Miaoli County (TW)

(72) Inventor: Chia-Ping Tseng, Miaoli County (TW)

(73) Assignee: Innolux Corporation, Miaoli County (TW)

(21) Appl. No.: 19/079,421

(22) Filed: Mar. 13, 2025

Related U.S. Application Data
(60) Provisional application No. 63/575,854, filed on Apr. 8, 2024.

(30) Foreign Application Priority Data
Oct. 16, 2024 (CN) 202411446416.6

(51) Int. Cl. H01L 23/538; H01L 21/48; H01L 21/66; H01L 23/00; H01L 23/15; H01L 23/31

(52) U.S. Cl. CPC H01L 23/5384; H01L 21/486; H01L 22/12; H01L 23/15; H01L 23/3128; H01L 23/5386; H01L 24/16; H01L 2224/16227; H01L 2924/1511

(57) ABSTRACT

The present disclosure provides an electronic device and a method for manufacturing the same. The electronic device includes a carrier substrate having a first thickness in a first direction, a through-hole penetrating the carrier substrate, a seed layer structure disposed on the carrier substrate and extending into the through-hole, a conductive element disposed in the through-hole, and a circuit structure disposed on the conductive element. The seed layer structure includes a plurality of seed layers. A first seed layer among the plurality of seed layers includes two neighboring sections having a first gap in the first direction of the carrier substrate in which a ratio of the first gap to the first thickness ranges from 0.01% to 0.1%.

### CROSS-REFERENCE TO RELATED APPLICATION

This application claims the priority benefit of U.S. provisional application Ser. No. 63/575,854, filed on Apr. 8, 2024, and China application serial no. 202411446416.6, filed on Oct. 16, 2024. The entirety of each of the above-mentioned patent applications is hereby incorporated by reference herein and made a part of this specification.

### BACKGROUND

### Technical Field

The present disclosure relates to an electronic device and a method manufacturing the same, and particularly relates to an electronic device with good reliability and a method manufacturing the same.

### Description of Related Art

In current semiconductor packaging technology, mounting electronic units with different functions on the same substrate is one of means to improve the performance of electronic devices. However, as the sizes of the electronic devices continue to develop towards light, thin, short, and small aspects, and the user's requirements to the performances of the electronic devices continue to increase, the density of the electronic units mounted on the aforementioned substrate is increased as well. This results in a continuous increase in the aspect ratio of the conductive vias penetrating the aforementioned substrate, for example, the aspect ratio may be at least as high as 9 or above. As such, it may be hard for the conductive vias to meet the current or future requirements in terms of the reliability and/or the process time.

### SUMMARY

The present disclosure provides an electronic device in which a first seed layer among a plurality of seed layers includes two neighboring sections in a through hole, the two neighboring sections are spaced apart by a gap in a first direction in the carrier substrate, and the ratio of the gap to the thickness of the carrier substrate is in a range of 0.01% to 0.1%. As such, a conductive element formed in the through hole can be well filled into the through hole, so that the defects caused by the high aspect ratio (for example, there may be a void existing in the conductive element having the high aspect ratio, and the void may cause a negative effect on the resistivity of the conductive element or may even cause a disconnection issue when the void is too large) can be improved, and therefore the reliability of the electronic device can be improved.

The present disclosure provides a method for manufacturing an electronic device in which a first seed layer in the seed layer structure is formed to include two neighboring sections in a through hole, and the two neighboring sections are spaced apart by a gap in a first direction in the carrier substrate. The method includes a step of determining the continuity of the seed layer structure in the through hole by measuring the gap. When the gap is greater than or equal to 0.1 μm, an auxiliary seed layer is provided between the two neighboring sections of the first seed layer before providing a conductive element in the through hole. As a result, the conductive element subsequently formed in the through hole can be well filled into the through hole, so that the aforementioned defects caused by the high aspect ratio can be improved, and therefore the reliability of the electronic device can be improved.

According to an embodiment of the present disclosure, the electronic device includes a carrier substrate, a through hole, a seed layer structure, a conductive element, and a circuit structure. The carrier substrate has a first thickness in a first direction. The through hole penetrates through the carrier substrate. The seed layer structure is disposed on the carrier substrate and extends into the through hole. The conductive element is disposed in the through hole. The circuit structure is disposed on the conductive element. The seed layer structure includes a plurality of seed layers. A first seed layer among the plurality of seed layers includes two neighboring sections in the through hole. The two neighboring sections have a first gap G1 in the first direction in the carrier substrate, and the ratio of the first gap to the first thickness is in a range of 0.01% to 0.1%.

According to an embodiment of the present disclosure, a method for manufacturing an electronic device includes following steps. A carrier substrate is provided. A through hole is provided in the carrier substrate. A seed layer structure is provided on the carrier substrate and extends into the through hole, the seed layer structure includes a first seed layer including two neighboring sections in the through hole, and the two neighboring sections have a first gap in a first direction in the carrier substrate. The first gap is measured to determine the continuity of the seed layer structure in the through hole. When the first gap is less than 0.1 μm, a conductive element is provided in the through hole. When the first gap is greater than or equal to 0.1 μm, an auxiliary seed layer is provided between the two neighboring sections of the first seed layer before providing the conductive element in the through hole.

Based on the above, in the electronic device of the embodiment of the present disclosure, the first seed layer among the plurality of seed layers includes the two neighboring sections in the through hole, the two neighboring sections are spaced apart by the first gap in the first direction in the carrier substrate, and the ratio of the first gap to the thickness of the carrier substrate is in a range of 0.01% to 0.1%. As such, the conductive element formed in the through hole can be well filled into the through hole, so that the defects caused by the high aspect ratio (for example, there may be a void existing in the conductive element having the high aspect ratio, and the void may cause a negative effect on the resistivity of the conductive element or may even cause a disconnection issue when the void is too large) can be improved, and therefore the reliability of the electronic device can be improved.

On the other hand, in the method for manufacturing the electronic device of the embodiment of the present disclosure, the first seed layer in the seed layer structure is formed to include the two neighboring sections in the through hole, and the two neighboring sections are spaced apart by the first gap in the first direction in the carrier substrate. The method includes a step of determining the continuity of the seed layer structure in the through hole by measuring the first gap. When the first gap is greater than or equal to 0.1 μm, an auxiliary seed layer is provided between the two neighboring sections of the first seed layer before providing the conductive element in the through hole. As a result, the conductive element subsequently formed in the through hole can be well filled into the through hole, so that the aforementioned defects caused by the high aspect ratio can be improved, and therefore the reliability of the electronic device can be improved.

To make the features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic view of an electronic device according to an embodiment of the present disclosure.

FIG. 2A to FIG. 2F are enlarged schematic views of the region R1 in FIG. 1 according to different embodiments.

FIG. 3 is a flow chart of a method for manufacturing an electronic device according to an embodiment of the present disclosure.

FIG. 4 is a cross-sectional schematic view of an electronic device according to another embodiment of the present disclosure.

FIG. 5 is a cross-sectional schematic view of an electronic device according to yet another embodiment of the present disclosure.

### DESCRIPTION OF THE EMBODIMENTS

The disclosure can be understood with reference to the following detailed description in conjunction with the accompanying drawings. It should be noted that, for ease of understanding by readers and for the concision of the illustration, multiple drawings in the disclosure only depict a part of the package structure, and certain elements in the drawings are not drawn according to actual scale. In addition, the number and size of each element in the drawings are for illustration only, and are not intended to limit the scope of the disclosure. For example, the relative sizes, thicknesses and positions of various layers, regions and/or structures may be reduced or enlarged for clarity.

Certain terms may be used throughout the disclosure and the claims to refer to specific elements. Those skilled in the art will understand that electronic device manufacturers may refer to the same elements by different names. The disclosure does not intend to distinguish between elements that have the same function but have different names. In the following description and claims, the words including “having” and “including” are open-ended words, and thus should be interpreted as meaning “including but not limited to.”

In this disclosure, “one element being disposed on another element” is used for convenience to describe the relative position between the element and the another element, and is not intended to limit the process steps or sequence of the element and the another element.

Directional terms mentioned herein, such as “up,” “down,” “front,” “rear,” “left,” “right,” and the like refer only to the directions of the drawings. Accordingly, the directional terms used are for illustration, and are not intended to limit the disclosure. It should be understood that when an element or film layer is referred to as being “disposed on” or “connected to” another element or film layer, the element or the film layer may be directly on or connected to the another element or film layer, or intervening elements or film layers may also be present in between (non-direct circumstances). In contrast, when an element or film layer is referred to as being “directly on” or “directly connected to” another element or film layer, no intervening elements or film layers are present in between. In addition, when the element or film layer is referred to as overlapping another element, the element or film layer at least partially overlaps the another element or film layer.

In the text, the terms “about,” “approximately,” “essentially,” or “substantially” usually implies that a value is within 10% of a given value or range, or within 5%, 3%, 2%, 1%, or 0.5% of a given value or range. In addition, the description “a given range from a first value to a second value” or “a given range between a first value and a second value” implies that the given range includes the first value, the second value, and other values in between.

In some embodiments of the disclosure, terms related to bonding and connection, such as “connection,” “interconnection,” and the like, unless otherwise specified, may mean that two structures are in direct contact, or may also mean that two structures are not in direct contact, in which there are other structures provided between these two structures. The terms related to bonding and connection may also include the case where both structures are movable, or both structures are fixed. Furthermore, the terms “electrically connected” or “coupled” includes any direct and indirect means of electrical connection.

In the embodiments provided later, the same or similar reference numerals are used to refer to the same or similar elements, and the descriptions will not be repeated. In addition, as long as the features of the various embodiments do not depart from or conflict with the spirit of the disclosure, the embodiments may be mixed and matched as desired. It is intended that the disclosure covers modifications and variations provided that they fall within the scope of the following claims and their equivalents. That is, in the following embodiments, technical features in several different embodiments may be replaced, reorganized, and mixed to complete other embodiments without departing from the spirit of the disclosure. Moreover, the terms such as “first” and “second” mentioned in the specification or the claims are only used to name different elements or to distinguish different embodiments or scopes, and are not intended to limit the upper or lower limit of the number of the elements, nor are they intended to limit the manufacturing order or disposition order of the elements.

In some embodiments of this disclosure, the thickness, length, and width may be obtained through a measurement using an optical microscope (OM). The thickness or the width may be obtained by measuring from a cross-sectional image in an electron microscope, but is not limited thereto.

In some embodiments of this disclosure, a surface roughness may be obtained by observing the surface undulations at an appropriate and consistent magnification through the electron microscope such as a scanning electron microscope (SEM) or a transmission electron microscope (TEM) and comparing the surface undulations per unit length (e.g., 10 μm). In some embodiments, the peak-to-valley of the surface undulation has a difference in distance by 0.15 μm to 1 μm. The appropriate magnification refers to a magnification that a roughness or an average roughness of at least one surface with at least 10 undulate peaks is observed in the field of view. Each of layers shown in the accompanying drawings of this disclosure may all have rough surfaces. It is worth noting that the rough surfaces of the aforementioned layers may refer to the high and low undulations presented in the cross-sectional view when observing the surfaces of each layer through the electron microscope.

The manufacturing process of the electronic device in this disclosure may be, for example, applied in a wafer-level package (WLP) process or a panel-level package (PLP) process, and may be a chip-first process or a chip-last-RDL-first process. The electronic device described in this disclosure may be applied to power modules, semiconductor package devices, display devices, light-emitting devices, backlight devices, antenna devices, silicon photonics co-packaged devices, sensing devices or stitching devices, but is not limited thereto.

The exemplary embodiments of this disclosure are described in the following for example, and the same reference numerals used in the figures and descriptions are represented to the same or similar portions.

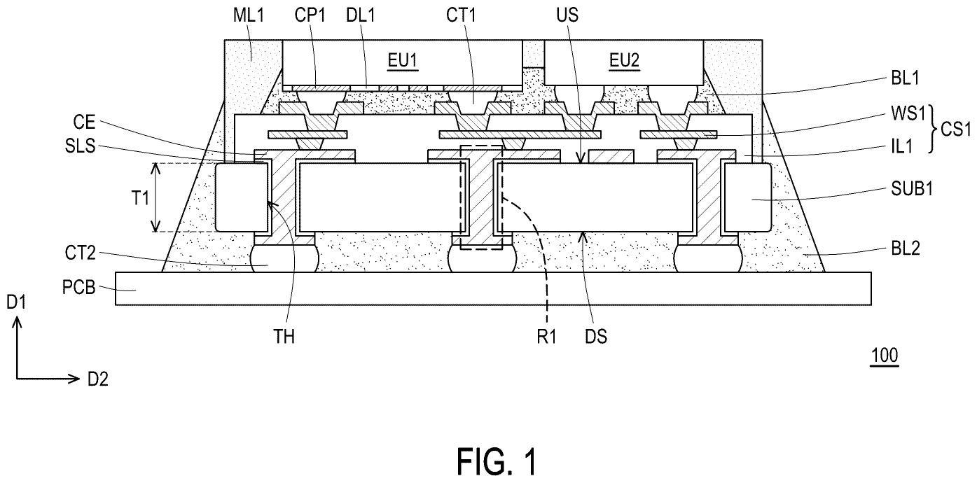

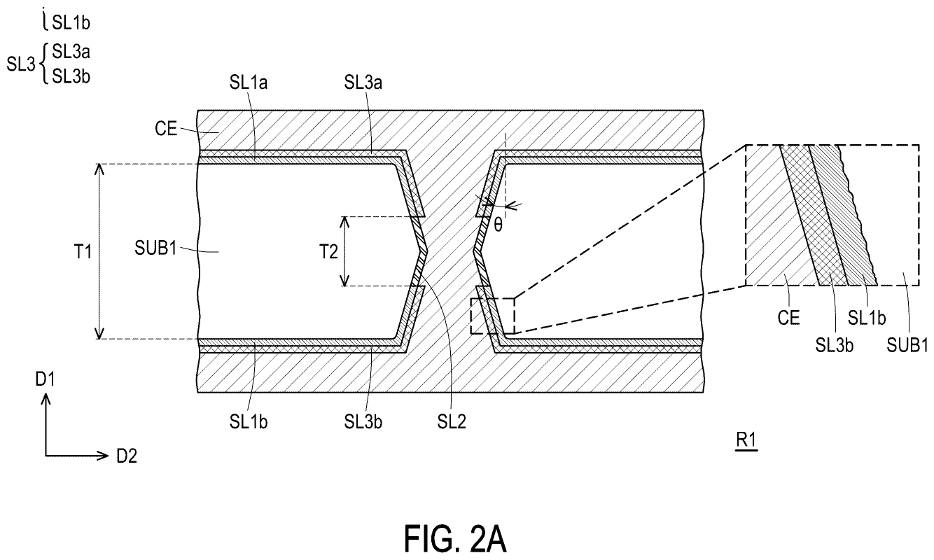

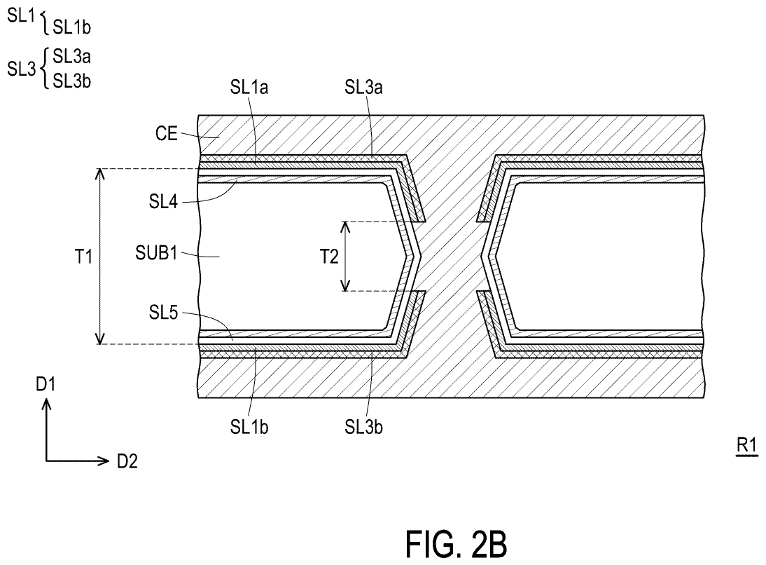

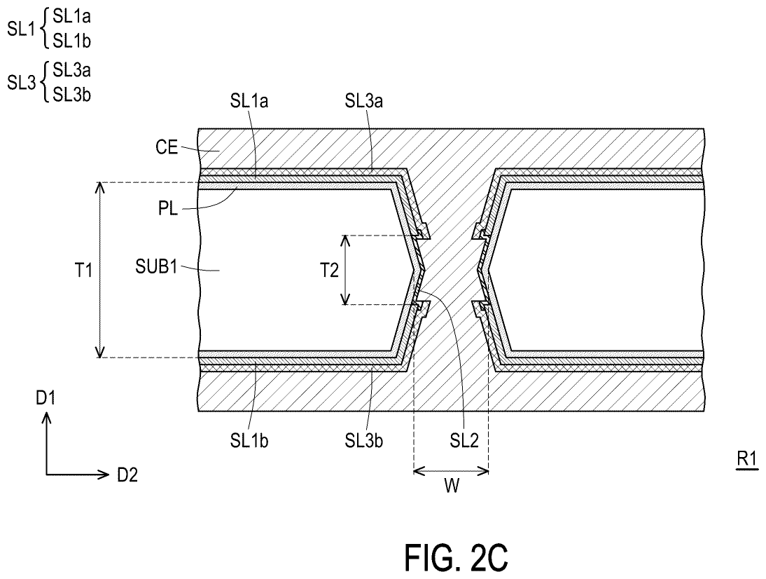

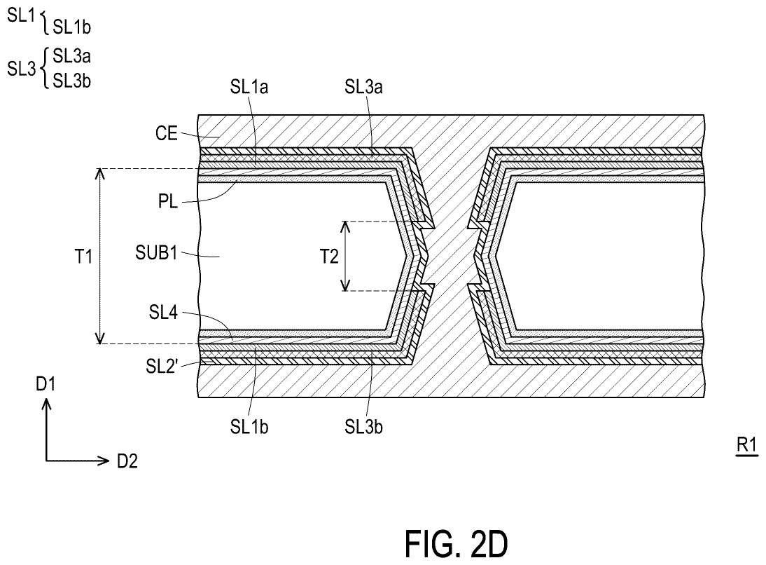

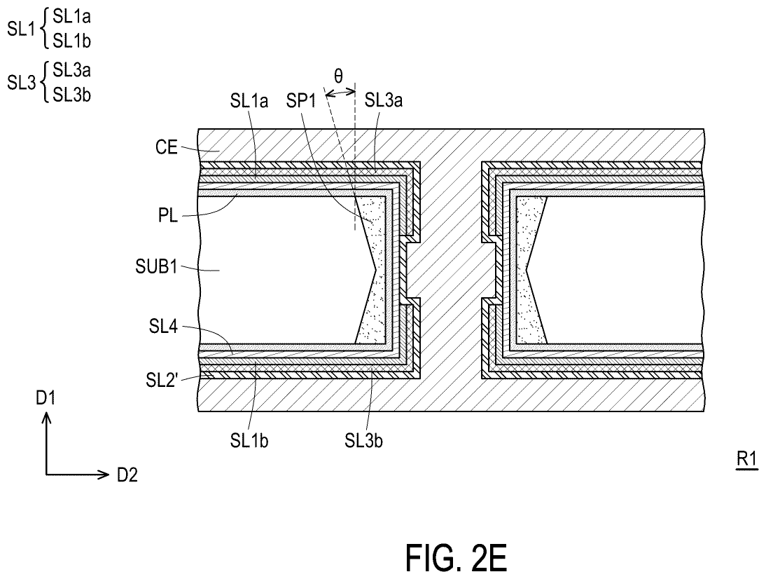

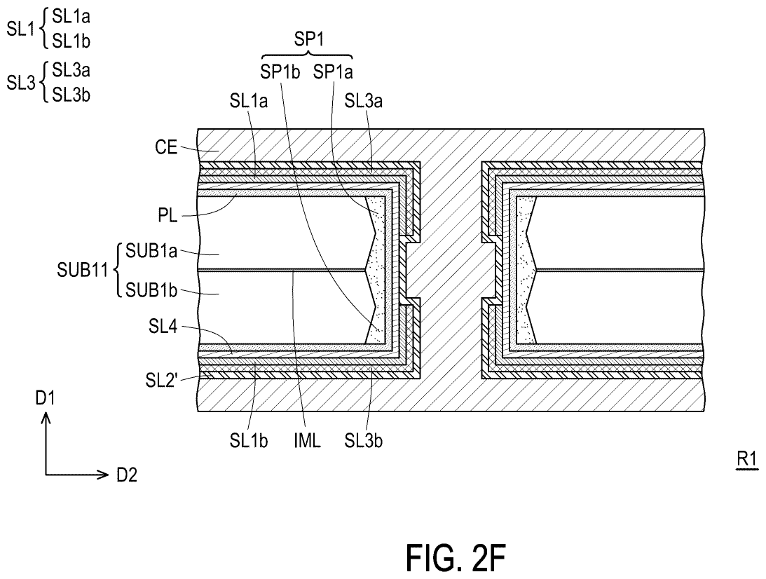

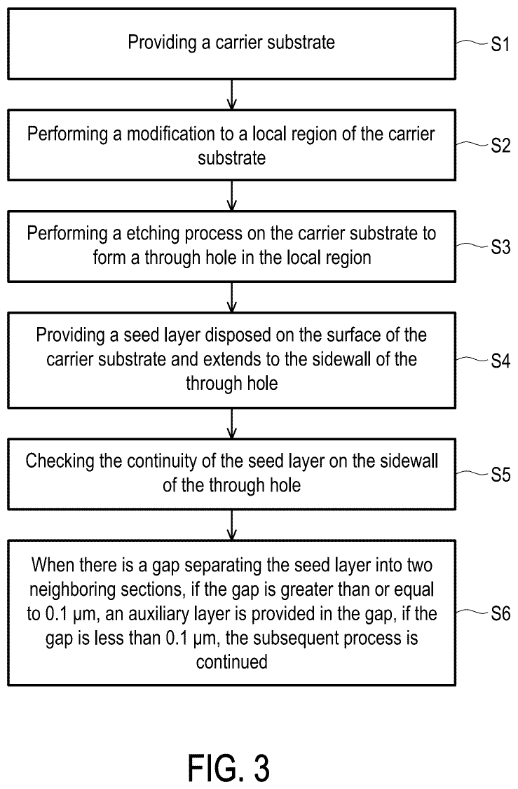

FIG. 1 is a cross-sectional schematic view of an electronic device according to an embodiment of the present disclosure. FIG. 2A to FIG. 2F are enlarged schematic views of the region R1 in FIG. 1 according to different embodiments. FIG. 3 is a flow chart of a method for manufacturing an electronic device according to an embodiment of the present disclosure.

Referring to FIG. 1, an electronic device 100 may include a carrier substrate SUB1, a through hole TH penetrating through the carrier substrate SUB1, a seed layer structure SLS disposed on the carrier substrate SUB1 and extending into the through hole TH, a conductive element CE disposed in the through hole TH, and a circuit structure CS1 disposed on the conductive element CE. In some embodiments, the electronic device 100 may also include an electronic unit EU1 or EU2 electrically connected to the conductive element CE through the circuit structure CS1.

The carrier substrate SUB1 may include polyimide, glass, silicon, or other suitable substrate materials. In some embodiments, the carrier substrate SUB1 may be a glass substrate including glass. The carrier substrate SUB1 may include a first thickness T1 in a first direction (e.g., direction D1). The first thickness T1 of the carrier substrate SUB1 may range from 50 μm to 1000 μm. In some embodiments, the light transmittance of the carrier substrate SUB1 may be at least greater than or equal to 90%, where the light may include white light. The coefficient of thermal expansion (CTE) of the carrier substrate SUB1 may range from 2 ppm/° C. to 10 ppm/° C. This design may buffer the potential risk of the warpage when subsequent elements are formed on the carrier substrate SUB1.

The through hole TH that penetrates through the carrier substrate SUB1 may be formed on the carrier substrate SUB1 by performing drilling processes, etching processes, or combinations thereof. For example, a laser drilling process may be performed on the upper surface US and the lower surface DS of the carrier substrate SUB1, which are opposite to each other in the first direction (e.g., direction D1), to form the through hole TH penetrating through the carrier substrate SUB1, or the laser drilling process may be performed on at least one surface of the carrier substrate SUB1 to form the through hole TH penetrating through the carrier substrate SUB1, but is not limited thereto. In some other embodiments, a modification process (e.g., a laser modification process) and an etching process may be performed on at least one surface of the carrier substrate SUB1 to form the through hole TH in the carrier substrate SUB1. In some embodiments, the etching processes may include an acid etching, an alkaline etching, or a combination thereof. In some embodiments, the extension line of the sidewall of the through hole TH has an angle θ with the carrier substrate SUB1 in the first direction (e.g., direction D1), where the angle θ may be greater than or equal to 0 degree and less than or equal to 20 degrees. The through hole TH has a minimum width position in the second direction (e.g., direction D2) (the position where the width W shown in FIG. 2C), and the through hole TH has a maximum width position in the second direction (e.g., direction D2), where the extension line of the sidewall is the extension line between the minimum width position and the maximum width position. In some embodiments, the sidewall of the through hole TH may have a first roughness r1, and the upper surface US and the lower surface DS of the carrier substrate SUB1 may have a second roughness r2 and a third roughness r3 respectively, where the first roughness r1 may be smaller than the second roughness r2 and the third roughness r3 (as shown in FIG. 2A). Through the above design, the skin effect of the electronic device 100 may be reduced, but is not limited thereto.

The seed layer structure SLS may be disposed on the sidewall of the through hole TH, or the seed layer structure SLS may be disposed on at least a portion of the upper surface US, at least a portion of the lower surface DS of the carrier substrate SUB1, and extend into the through hole TH. In this embodiment, the seed layer structure SLS may include a plurality of seed layers stacked along the first direction (e.g., direction D1). As shown in FIG. 2A to FIG. 2F, the seed layer SL1 among the plurality of seed layers may include two sections SL1a and SL1b that are neighboring to each other and spaced apart from each other in the through hole TH. The neighboring two sections SL1a and SL1b are spaced apart from each other in the first direction (e.g., in direction D1) by a first gap T2 of the carrier substrate SUB1 in the first direction (corresponding to the gap between the two sections SL1a and SL1b spaced apart in the first direction). The ratio of the first gap T2 to the first thickness T1 (T2/T1*100%) is in a range of 0.01% to 0.1%. As such, even if the seed layer SL1 includes two sections SL1a and SL1b that are adjacent to each other and spaced apart in the through hole TH, the conductive element CE subsequently formed thereon can also be well filled into the through hole TH, as so to improve the defects caused by the aforementioned high aspect ratio (for example, there may be a void existing in the conductive element having the high aspect ratio, and the high void ratio may cause a negative effect on the resistivity of the conductive element or may even cause a disconnection issue when the void is too large), and thereby improving the reliability of the electronic device 100, but is not limited thereto. In some embodiments, the conductive element CE may have a void ratio less than 5 vol % in the through hole TH.

In some embodiments, the seed layer SL1 may be formed, for example, by a chemical vapor deposition (CVD) process, a sputtering process, an atomic layer deposition (ALD) process, other suitable deposition processes, or a combination thereof. The seed layer SL1 may include any suitable conductive material, such as titanium (Ti), titanium nitride (TiN), tungsten (W), nickel (Ni), tantalum (Ta), nitrides, carbides, other suitable metals, or alloys thereof, or combinations of the aforementioned materials. In some embodiments, the seed layer SL1 may be in direct contact with the carrier substrate SUB1.

In some embodiments, as shown in FIG. 1 and FIG. 3, the seed layer SL1 may be formed through the following method for manufacturing the electronic device 100. First, a carrier substrate SUB1 is provided (step S1). Then, a through hole TH is formed in the carrier substrate SUB1. In some embodiments, the through hole TH may be formed in the carrier substrate SUB1 through the following steps. First, a modification process is performed on a local region of the carrier substrate SUB1 (step S2). In some embodiments, the local region of the carrier substrate SUB1 may be modified through, for example, a laser modification process. The modified local region may have, for example, reduced mechanical strength. Next, the modified local region of the carrier substrate SUB1 may be etched through, for example, an etching process to form the through hole TH in the local region (step S3). Then, the seed layer SL1 disposed on the surface of the carrier substrate SUB1 and extending to the sidewall of the through hole TH is provided (step S4). The local region referred in this disclosure may be a region within the carrier substrate SUB1 that connects at least a portion of the upper surface US to at least a portion of the lower surface DS, and in a cross-sectional view, the range of the local region is smaller than the range of the carrier substrate SUB1.

The aforementioned method for manufacturing the electronic device 100 may also include a step of determining the continuity of the seed layer SL1 located on the sidewall of the through hole TH (step S5). In this embodiment, as shown in FIG. 2A, the seed layer SL1 may include two sections SL1a and SL1b that are neighboring to each other and spaced apart from each other in the through hole TH. The two neighboring sections SL1a and SL1b are spaced apart by a gap (corresponding to the first gap T2 in the carrier substrate SUB1) in a first direction (e.g., direction D1) in the carrier substrate SUB1, wherein the through hole TH may have an arched corner design, which may reduce the risk of cracking on the seed layer SL1 or on other film layers, but is not limited thereto. In the case where the ratio of the gap to the thickness of the carrier substrate SUB1 (T2/T1*100%) falls within the aforementioned range (i.e., being within the range of 0.01% to 0.1%), a conductive element CE is then provided in the through hole TH. In other words, even in the case where there is a gap that separates the seed layer into two neighboring sections, the conductive element CE subsequently formed in the through hole TH is not affected by the gap significantly as long as the ratio of the gap to the thickness of the substrate falls within the above range (i.e., being within the range of 0.01% to 0.1%), and thus the conductive element CE can still be well filled into the through hole TH. In some embodiments, in the case where the gap is less than 0.1 μm, the subsequent process, such as the process of providing the conductive element CE in the through hole TH, is continued (step S6).

When the gap is larger and thus the ratio (T2/T1*100%) exceeds the aforementioned range (i.e., being out of the range of 0.01% to 0.1%), an auxiliary seed layer SL2 between the two neighboring sections SL1a and SL1b of the seed layer SL1 (as shown in FIG. 2A) is provided, so that the conductive element CE subsequently formed in the through hole TH can be well filled into the through hole TH, and thus the defects caused by high aspect ratio (for example, there may be a void existing in the conductive element having the high aspect ratio, and the void may cause a negative effect on the resistivity of the conductive element or may even cause a disconnection issue when the void is too large) can be improved, so that the reliability of the electronic device 100 can be enhanced. In other words, when there is a gap that separates the seed layer into two neighboring sections, an auxiliary seed layer SL2 is formed in the gap if the ratio of the gap to the thickness of the substrate exceeds the above range (i.e., being out of the range of 0.01% to 0.1%), so that the conductive element CE subsequently formed in the through hole TH can be well filled into the through hole TH. In some embodiments, when the gap is greater than or equal to 0.1 μm, an auxiliary seed layer SL2 between the two neighboring sections SL1a and SL1b of the seed layer SL1 is provided before providing the conductive element CE in the through hole TH, so that the conductive element CE subsequently formed in the through hole TH can be well filled into the through hole TH. The auxiliary seed layer SL2 may include any suitable conductive material, such as copper (Cu), graphene, but is not limited thereto.

In some embodiments, the auxiliary seed layer SL2 may be formed on the carrier substrate SUB1 between the two neighboring sections SL1a and SL1b of the seed layer SL1 through methods such as a chemical deposition process or an ink jet process. In other embodiments, the auxiliary seed layer SL2 may be formed by coating a conductive adhesive such as a silver paste or a copper paste on the carrier substrate SUB1 between the two neighboring sections SL1a and SL1b of the seed layer SL1. In some alternative embodiments, the auxiliary seed layer SL2 may include conductive polymer materials. The conductive polymer materials may be materials with high adhesion to the carrier substrate SUB1, so that the auxiliary seed layer SL2 can be selectively formed on the carrier substrate SUB1 between the two neighboring sections SL1a and SL1b of the seed layer SL1, without forming on the surface of the seed layer SL1. In this way, it may be beneficial to improve the negative effect caused by the excessively large gap and may not bring other risks to the seed layer SL1 as well. For example, the auxiliary seed layer SL2 may select materials that have excellent adhesion to the carrier substrate SUB1 or excellent adhesion to both the carrier substrate SUB1 and the metal. In some embodiments, the materials of the auxiliary seed layer SL2 may include composite materials, such as a composite material of siloxane mixed with a conductive material, so that the auxiliary seed layer SL2 can be well formed on the carrier substrate SUB1 between the two neighboring sections SL1a and SL1b of the seed layer SL1. In other embodiments, the auxiliary seed layer SL2 may also be formed, for example, through an electroplating process, a chemical vapor deposition (CVD) process, a sputtering process, an atomic layer deposition (ALD) process, a resistance heating evaporation process, an electron beam evaporation process, other suitable deposition manners, or combinations thereof.

In some embodiments, as shown in FIG. 2A, the seed layer structure SLS may further include a seed layer SL3 disposed on the seed layer SL1. The seed layer SL3 may include any suitable conductive material, for example, copper (Cu). The seed layer SL3 may include two sections SL3a and SL3b that are neighboring to each other and spaced apart from each other in the through hole TH. The two neighboring sections SL3a and SL3b are spaced apart from each other by a second gap G2 in the first direction (e.g., direction D1) in the carrier substrate SUB1. In some embodiments, the second gap may correspond to the first gap T2 of the carrier substrate SUB1, which indicate that a ratio of the second gap to the first thickness is in a range of 0.01% to 0.1%. In some embodiments, the second gap is less than the first gap.

In some embodiments, as shown in FIG. 2B, the seed layer structure SLS may include a seed layer SL4 and a seed layer SL5 sequentially disposed on the surface of the carrier substrate SUB1 and extending to the surface of the through hole TH. In some embodiments, the through hole TH may have a chamfering design, which may reduce the risk of cracking on the seed layer SL1 or other film layers, but is not limited thereto. The aforementioned discontinuous seed layer SL1 and seed layer SL3 may be formed on the continuous seed layer SL4 and seed layer SL5. In this embodiment, since the seed layer SL4 and seed layer SL5 are still continuous film layers in the through hole TH, the auxiliary seed layer SL2 provided between the two neighboring sections SL1a and SL1b of the seed layer SL1 may be omitted optionally. The seed layer SL4 may include any suitable conductive material, for example, titanium (Ti), titanium nitride (TiN), other suitable metals, or their alloys or combinations thereof. The seed layer SL5 may include any suitable conductive material, for example, ruthenium (Ru), palladium (Pd), platinum (Pt), gold (Au), their alloys or other suitable metal materials. The seed layer SL4 and the seed layer SL5 may each be formed by an atomic layer deposition (ALD) process or other processes with good gap-filling capability, but is not limited thereto.

In some embodiments, as shown in FIG. 1 and FIG. 2C, the electronic device 100 may further include a buffer layer PL disposed between the carrier substrate SUB1 and the seed layer structure SLS. The buffer layer PL may be disposed between the carrier substrate SUB1 and the seed layer SL1. The seed layer SL1 may be formed on the buffer layer PL, and the auxiliary seed layer SL2 between the two neighboring sections SL1a and SL1b of the seed layer SL1 may be provided on the buffer layer PL. The buffer layer PL may be beneficial to improve the negative effect on the carrier substrate SUB1 caused by the aforementioned process of forming the through hole TH. For example, the buffer layer PL may repair defects such as micro cracks generated while the through hole TH is formed in the carrier substrate SUB1 through the process of modification treatment (e.g., laser modification process) and etching process. In some other embodiments, for instance, when the carrier substrate SUB1 is a glass substrate, the buffer layer PL may mitigate the difference in coefficient of thermal expansion (CTE) between the carrier substrate SUB1 and the conductive element CE subsequently formed in the through hole TH, so as to improve the adhesion of the conductive layer formed in the through hole TH. In this embodiment, the buffer layer PL is at least disposed on the sidewall of the through hole TH and extends to the upper surface and lower surface of the carrier substrate SUB1 that are opposite to each other in the first direction (e.g., direction D1).

The buffer layer PL may include a single layer or stacked layers. The buffer layer PL may include organic materials or inorganic materials. The organic materials may include, but are not limited to, polyimide (PI), parylene, benzocyclobutene (BCB), epoxy resin, polycarbonate (PC), polyethylene terephthalate (PET), polyethylene naphthalate (PEN), or combinations thereof. The toughness of the buffer layer PL may be ranging from 0.1 kJ/m² to 100 KJ/m². The inorganic materials may include, but are not limited to, silicon oxide, silicon nitride, nitrides, oxides, carbides, or combinations thereof. Furthermore, the buffer layer PL may include at least one organic material layer, or the buffer layer PL may include at least one organic material layer and one inorganic material layer formed on the organic material layer, or the buffer layer PL may include at least two organic material layers and one inorganic material layer formed between the two organic material layers, that is, the organic material layers and the inorganic material layers may be stacked alternately. The thickness of the buffer layer PL may be ranging from about 0.01 μm to about 10 μm. In this embodiment, the maximum thickness of the buffer layer PL may be less than about 1 μm. The dissipation factor (Df) of the buffer layer PL may be less than 0.01 at 10 GHz. The ratio of the thickness of the buffer layer PL to the width W of the through hole TH may be ranging from about 0.02 to about 0.2. For example, along a direction (e.g., direction D2) perpendicular to the first direction (e.g., direction D1), the through hole TH has a minimum width W at a first position (as shown in FIG. 2C), and the ratio of the thickness of the buffer layer PL disposed at the first position to the width W of the through hole TH may be ranging from about 0.02 to about 0.2, so that the protective effect of the buffer layer PL may be enhanced, but is not limited thereto.

In some embodiments, as shown in FIG. 2D, the electronic device 100 may include a buffer layer PL disposed between the carrier substrate SUB1 and the seed layer structure SLS, and the seed layer structure SLS may include a seed layer SLA disposed on the buffer layer PL. The aforementioned discontinuous seed layer SL1 and seed layer SL3 may be formed on the continuous seed layer SL4. In this embodiment, the auxiliary seed layer SL2′ may be provided on the seed layer SL3 and formed on the seed layer SL4 between two neighboring sections SL1a and SL1b of the seed layer SL1. In this embodiment, the auxiliary seed layer SL2′ may also be provided between two neighboring sections SL3a and SL3b of the seed layer SL3.

In some embodiments, after providing the seed layer structure SLS, the continuity of the seed layer structure SLS in the through hole TH may be determined. For example, after sequentially forming the seed layer SL1 and the seed layer SL3 on the seed layer SL4, the continuity of the seed layer structure SLS in the through hole TH may be determined by measuring the gap between two neighboring sections SL1a and SL1b of the seed layer SL1 and the gap between two neighboring sections SL3a and SL3b of the seed layer SL3. Then, based on the aforementioned method of determining the continuity, the auxiliary seed layer SL2′ may be formed in the gap.

In some embodiments, as shown in FIG. 2E, the electronic device 100 may also include a spacer SP1 disposed between the carrier substrate SUB1 and the buffer layer PL, which may be beneficial for improving the reliability of the carrier substrate SUB1. In some embodiments, the thickness of the spacer SP1 may be greater than the thickness of the buffer layer PL, where the thickness in this embodiment is referred to, for example, the maximum thickness measured along the second direction (e.g., direction D2). In some embodiments, along the second direction D2, a profile of a first side surface of the spacer SP1 adjacent to the buffer layer PL is different from a profile of a second side surface of the spacer SP1 away from the buffer layer PL. In some embodiments, the angle θ between an extension line of the sidewall of the through hole TH and the first direction D1 is greater than or equal to an angle between an extension line of the first side surface of the spacer SP1 and the first direction D1. According to the above design, the angle between the extension line of the sidewall of the through hole where the conductive element CE is filled therein may be adjusted. For example, the through hole where the conductive element CE is filled therein may be adjusted from the through hole TH having the angle θ with the carrier substrate SUB1 in the first direction (e.g., direction D1) to the through hole having a sidewall defining by the second side surface of the spacer SP1. In some embodiments, the dissipation factor (Df) of the spacer SP1 may be different from the dissipation factor (Df) of the buffer layer PL. For example, the dissipation factor (Df) of the spacer SP1 may be greater than the dissipation factor (Df) of the buffer layer PL, and the dissipation factor (Df) of the buffer layer PL may be less than 0.01 at 10 GHz. The spacer SP1 may include any suitable organic or inorganic material, such as polyimide (PI). In this embodiment, the electronic device 100 may include a buffer layer PL disposed between the seed layer structure SLS and the carrier substrate SUB1 and the spacer SP1, while the seed layer structure SLS may include a seed layer SL4 disposed on the buffer layer PL, and the aforementioned discontinuous seed layer SL1 and seed layer SL3 may be formed on the continuous seed layer SL4. In this embodiment, the auxiliary seed layer SL2′ may be provided on the seed layer SL3 and formed on the seed layer SL4 between two neighboring sections SL1a and SL1b of the seed layer SL1. In this embodiment, the auxiliary seed layer SL2′ may also be provided between two neighboring sections SL3a and SL3b of the seed layer SL3. In this embodiment, after providing the seed layer structure SLS, the continuity of the seed layer structure SLS in the through hole TH may be determined. For example, after sequentially forming the seed layer SL1 and the seed layer SL3 on the seed layer SL4, the continuity of the seed layer structure SLS in the through hole TH may be determined by measuring the gap between two neighboring sections SL1a and SL1b of the seed layer SL1 and the gap between two neighboring sections SL3a and SL3b of the seed layer SL3. Then, based on the aforementioned method of determining the continuity, the auxiliary seed layer SL2′ may be formed in the gap.

In some embodiments, as shown in FIG. 2F, the electronic device 100 may also include a spacer SP1 disposed between the carrier substrate SUB11 and the buffer layer PL. In this embodiment, the carrier substrate SUB11 may include stacked substrates SUB1a and SUB1b, wherein: the materials of the substrate SUB1a and the substrate SUB1b may be the same as or different from each other; the thicknesses of the substrate SUB1a and the substrate SUB1b may be the same as or different from each other; or the coefficients of the thermal expansion of the substrate SUB1a and the substrate SUB1b may be the same as or different from each other. For example, in the case where elements are formed on the substrate SUB1a and away from the substrate SUB1b, the thickness of substrate SUB1a may be less than the thickness of substrate SUB1b. The spacer SP1 may include a spacer SP1a disposed between the substrate SUB1a and the buffer layer PL, and a spacer SP1b disposed between the substrate SUB1b and the buffer layer PL. In some embodiments, the substrate SUB1a and the substrate SUB1b may be connected to each other through an intermediate layer IML. In some embodiments, the intermediate layer IML may include any suitable adhesive material or glass-like material. The thickness of the intermediate layer IML may be about 0.01 μm to about 1 μm. The dissipation factor (Df) of the intermediate layer IML may be less than 0.01 at 10 GHz. In this embodiment, the electronic device 100 may include a buffer layer PL disposed between the seed layer structure SLS and the carrier substrate SUB1 and the spacer SP1, while the seed layer structure SLS may include a seed layer SLA disposed on the buffer layer PL. The aforementioned discontinuous seed layer SL1 and seed layer SL3 may be formed on the continuous seed layer SL4. In this embodiment, the auxiliary seed layer SL2′ may be provided on the seed layer SL3 and formed on the seed layer SL4 between two neighboring sections SL1a and SL1b of the seed layer SL1. In this embodiment, the auxiliary seed layer SL2′ may also be provided between two neighboring sections SL3a and SL3b of the seed layer SL3. In this embodiment, after providing the seed layer structure SLS, the continuity of the seed layer structure SLS in the through hole TH may be determined. For example, after sequentially forming the seed layer SL1 and the seed layer SL3 on the seed layer SL4, the continuity of the seed layer structure SLS in the through hole TH may be determined by measuring the gap between two neighboring sections SL1a and SL1b of the seed layer SL1 and the gap between two neighboring sections SL3a and SL3b of the seed layer SL3. Then, the auxiliary seed layer SL2′ may be formed in the gap according to the aforementioned method of determining the continuity.

Back to FIG. 1, the conductive element CE may be disposed on the seed layer structure SLS. In some embodiments, the conductive element CE may be formed for example, through an electroplating process, a chemical vapor deposition (CVD) process, a sputtering process, an atomic layer deposition (ALD) process, a resistance heating evaporation process, an electron beam evaporation process, other suitable deposition processes, or combinations thereof. The conductive element CE may include conductive materials such as copper (Cu). In some embodiments, the conductive element CE may be formed by growing the seed layer structure SLS through the electroplating process.

The circuit structure CS1 may be disposed on the carrier substrate SUB1. The circuit structure CS1 may include an insulation layer IL1 formed on the carrier substrate SUB1 and a wiring structure WS1 formed in the insulation layer IL1. The insulation layer IL1 may include a plurality of insulation layers alternately stacked along the direction D1. The wiring structure WS1 may include a plurality of conductive patterns formed in the insulation layer IL1 and alternately stacked along the direction D1, and conductive vias connecting the conductive patterns. The wiring structure WS1 may include any suitable conductive material, such as copper, titanium, nickel, combinations or alloys thereof, but is not limited thereto. The insulation layer IL1 may include organic materials or inorganic materials. The organic materials include polyimide (PI), poly-p-xylylene (also known as Parylene), benzocyclobutene (BCB), epoxy resin, polycarbonate (PC), polyethylene terephthalate (PET), polyethylene naphthalate (PEN), polymers or other suitable organic materials, but are not limited thereto. The inorganic materials include silicon oxide, silicon nitride, silicon oxynitride or other suitable inorganic materials, but are not limited thereto.

The electronic unit EU1 or EU2 may be disposed on the circuit structure CS1 and electrically connected to the conductive element CE through the circuit structure CS1. The electronic units EU1 and EU2 may each include a die, a chip, an diode, an antenna unit, a memory unit, a photonic integrated circuit (PIC) unit, a sensor, or a structure related to the manufacturing processes for the semiconductor. In some embodiments, the electronic unit EU1 may include pads CP1, wherein the pads CP1 may be located on one side of the electronic unit EU1. In the embodiments where the electronic unit is a chip, the side having the pads CP1 is the front side of the chip (also known as the active surface), while the other side (or surface) opposite to the front side (or active surface) of the chip is the back side (or back surface). In this embodiment, the electronic unit EU1 may include a dielectric layer DL1 formed on the front side of the chip and surrounding the pads CP1. The dielectric layer DL1 may include any suitable dielectric material. In this embodiment, the electronic unit EU1 may be different from the electronic unit EU2. In this embodiment, the number of pads CP1 on different electronic units EU1 may be the same as or different from each other. According to some embodiments, the dimensions of the pads CP1 on different electronic units EU1 may be the same as or different from each other. The pads CP1 may include any suitable conductive material, such as copper (Cu), aluminum (Al), nickel (Ni), molybdenum (Mo), titanium (Ti), alloys or combinations thereof, or other suitable materials, but are not limited thereto. In this embodiment, “one element surrounding another element” may refer to the element that may be at least in contact with the side surface of the other element in the cross-sectional view. For example, as shown in FIG. 1, the dielectric layer DL1 may be in contact with the side surface of the pad CP1.

In some embodiments, the electronic device 100 may include a connection member CT1 disposed between the electronic unit EU1 or EU2 and the circuit structure CS1. The electronic unit EU1 or EU2 may be electrically connected to the circuit structure CS1 through the connection member CT1. In some embodiments, the connection member CT1 may include a solder ball. In some embodiments, the material of the connection member CT1 may include tin-silver (SnAg), tin, silver, nickel, gold, copper, conductive paste, or other suitable conductive materials, but is not limited thereto. In some embodiments, the electronic device 100 may include a connection member CT1 disposed between the electronic unit EU1 or EU2 and the circuit structure CS1 in which the connection member CT1 may be formed by a portion of the pad CP1 and a portion of the wiring structure WS1 in the circuit structure CS1 to achieve hybrid bonding.

In some embodiments, the electronic device 100 may include a printed circuit board PCB and a connection member CT2 disposed between the printed circuit board PCB and the carrier substrate SUB1. The printed circuit board PCB may be electrically connected to the conductive element CE through the connection member CT2. In some embodiments, the connection member CT2 may include a solder ball. In some embodiments, the material of the connection member CT2 may include tin-silver (SnAg), tin, silver, nickel, gold, copper, conductive adhesive, or other suitable conductive materials, but is not limited thereto.

In some embodiments, the electronic device 100 may include a buffer layer BL1 disposed between the electronic unit EU1 or EU2 and the carrier substrate SUB1 and surrounding at least one of the connection members CT1, so as to enhance the reliability of the electronic device 100. The buffer layer BL1 may include any suitable underfill material. In this embodiment, “one element surrounding another element” may refer to the element that may be at least in contact with the side surface of the other element in the cross-sectional view. For example, as shown in FIG. 1, the buffer layer BL1 may be in contact with the side surface of the connection member CT1.

In some embodiments, the electronic device 100 may include a buffer layer BL2 disposed between the carrier substrate SUB1 and the printed circuit board PCB and surrounding at least one of the connection members CT2, so as to enhance the reliability of the electronic device 100. The buffer layer BL2 may include any suitable underfill material. In this embodiment, “one element surrounding another element” may refer to the element that may be at least in contact with the side surface of the other element in the cross-sectional view. For example, as shown in FIG. 1, the buffer layer BL2 may be in contact with the side surface of the connection member CT2.

In some embodiments, the electronic device 100 may include an encapsulation layer ML1 on the carrier substrate SUB1 and surrounding the electronic units EU1 and EU2 and the circuit structure CS1. The encapsulation layer ML1 may prevent the electronic units EU1 and EU2 from being affected by the external moisture, and thus the reliability of the electronic device 100 can be improved. The encapsulation layer ML1 may include any suitable encapsulation material, for example, an epoxy molding compound (EMC), but is not limited thereto.

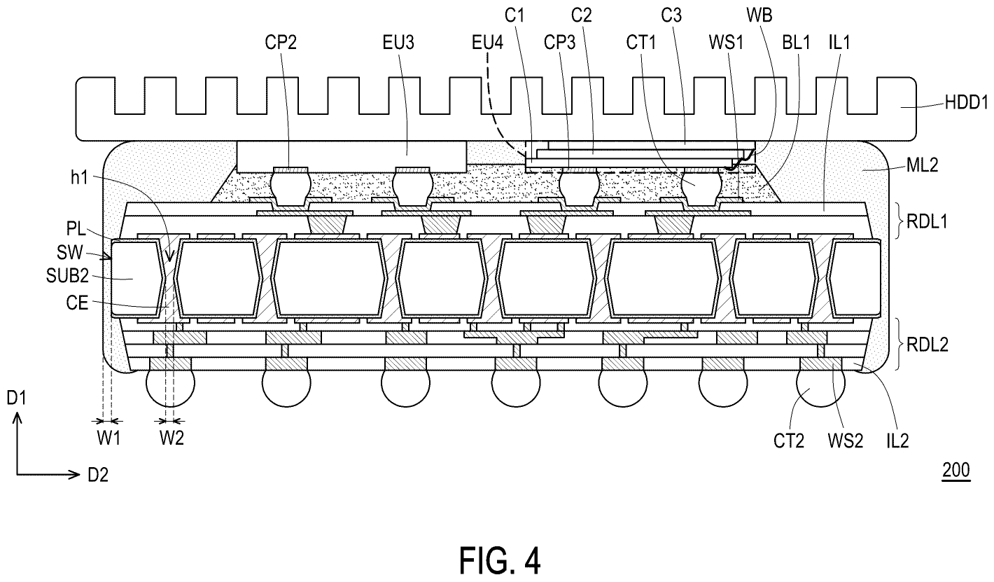

FIG. 4 is a cross-sectional schematic view of an electronic device according to another embodiment of the present disclosure. The electronic device 200 shown in FIG. 4 is similar to the electronic device 100 shown in FIG. 1. The main differences therebetween are relied on: the electronic device 200 includes electronic units EU3 and EU4, redistribution structures RDL1 and RDL2, and a heat dissipation element HDD1; and the encapsulation layer ML2 of the electronic device 200 surrounds the outer sidewall SW of the carrier substrate SUB2. Other identical or similar elements are represented by the same or similar reference numerals, and will not be repeated hereinafter.

As shown in FIG. 4, the redistribution structure RDL1 is electrically connected to the conductive element CE and formed on the upper surface of the carrier substrate SUB2. The electronic units EU3 and EU4 of the electronic device 200 may be disposed on the redistribution structure RDL1 (which may correspond to the circuit structure CS1 in FIG. 1) and may be electrically connected to the redistribution structure RDL1 through the connection members CT1. The redistribution structure RDL2 is electrically connected to the conductive element CE and formed on the lower surface of the carrier substrate SUB2. The redistribution structure RDL2 may electrically connect the electronic device 200 to the connection members of other components, elements, or devices through the connection members CT2, but is not limited thereto.

The redistribution structure RDL1 may include an insulation layer IL1 and a wiring structure WS1. The redistribution structure RDL2 may include an insulation layer IL2 and a wiring structure WS2. The insulation layers IL1 and IL2 may include a plurality of insulation layers alternately stacked along the direction D1. The wiring structures WS1, WS2 may include a plurality of conductive patterns formed in the insulation layers IL1, IL2 and alternately stacked along the direction D1, and a conductive via connecting the conductive patterns. The redistribution structures RDL1, RDL2 may be able to redistribute the wirings and/or to increase the fan-out area of the wirings, or different electronic elements may be electrically connected to each other through the redistribution structures. The method for forming the redistribution structures may include providing a stack of at least one insulation layer and at least one conductive layer and may include processes such as a photolithography process, an etching process, a surface treatment, a laser process, and an electroplating process. The surface treatment includes roughening the surface of the insulation layer or the conductive layer to enhance its adhesion ability. Alternatively, the redistribution structures RDL1 and RDL2 may be used as a substrate for the electrical interface wiring between one connection and another connection. The purpose of the redistribution structure is to extend the connections to wider gaps or redistribute the connections to another connection with different gaps. The insulation layers IL1 and IL2 may include polyimide (PI), photosensitive polyimide (PSPI), polybenzoxazole (PBO), benzocyclobutene (BCB), epoxy resin, Ajinomoto Build-up Film (ABF), silicon oxide (SiOx), silicon nitride (SiNx), any other suitable insulating materials or combinations thereof, but are not limited thereto. The wiring structures WS1 and WS2 may include any suitable conductive materials, such as copper, titanium, nickel, combinations or alloys of the above materials, but are not limited thereto. In some embodiments, the thicknesses of the insulation layers IL1 and IL2 may be greater than the thickness of the buffer layer PL. In some embodiments, the thicknesses of the insulation layers IL1 and IL2 may be in a range from 5 μm to 15 μm.

The electronic unit EU3 of the electronic device 200 may include pads CP2 in which the pads CP2 may be located on one side of the electronic unit EU3. In the embodiments where the electronic unit is a chip, the side having the pads CP2 is the front side (also known as the active surface) of the chip, while the other side (or surface) opposite to the front side (or active surface) of the chip is the back side (or back surface). In this embodiment, the number of pads CP2 on different electronic units EU3 may be the same as or different from each other. According to some embodiments, the dimensions of the pads CP2 on different electronic units EU3 may be the same as or different from each other. The pads CP2 may include any suitable conductive material, for example, copper (Cu), aluminum (Al), nickel (Ni), molybdenum (Mo), titanium (Ti), alloys or combinations of the above materials, or other suitable materials, but are not limited thereto.

The electronic unit EU4 may include a plurality of chips C1, C2, C3 stacked on each other in the direction D1. The Chips C1, C2, and C3 may be electrically connected to each other through the wire bonding. For example, the chips C1, C2, and C3 may be electrically connected to each other through the conductive wires WB. In some embodiments, the electronic unit EU4 may be electrically connected to the connection members CT1 through the pads CP3 disposed between the connection members CT1 and the electronic unit EU4. The conductive wires WB may include any suitable conductive material. The pads CP3 may include any suitable conductive material, for example, copper (Cu), aluminum (Al), nickel (Ni), molybdenum (Mo), titanium (Ti), alloys or combinations of the above materials, or other suitable materials, but are not limited thereto.

In some embodiments, the electronic device 200 may include an encapsulation layer ML2 surrounding the carrier substrate SUB2 and the electronic units EU3 and EU4. The encapsulation layer ML2 may include any suitable encapsulation material, for example, an epoxy molding compound (EMC), but is not limited thereto. In this embodiment, “one element surrounding another element” may refer to the element that may be at least in contact with the side surface of the other element in the cross-sectional view. For example, as shown in FIG. 4, the encapsulation layer ML2 may be at least in contact with the side surfaces of the carrier substrate SUB2 and the electronic units EU3 and EU4.

The encapsulation layer ML2 may surround the outer sidewall SW of the carrier substrate SUB2 to protect the carrier substrate SUB2, so that the concerns of cracking on the carrier substrate SUB2 can be avoided and thus the reliability of the electronic device 200 can be improved. In this embodiment, the encapsulation layer ML2 may cover a portion of the top surface of the redistribution structure RDL2 (e.g., the portion at the corners).

The heat dissipation element HDD1 of the electronic device 200 may be in contact with the back surfaces of the electronic units EU3 and EU4, allowing the heat generated during the operation of the electronic units EU3 and EU4 to be dissipated through the heat dissipation element HDD1. In some embodiments, the back surfaces of the electronic units EU3 and EU4 may be exposed from the encapsulation layer ML2 through grinding. In this embodiment, the top surface of the encapsulation layer ML2 may be coplanar with the back surfaces of the electronic units EU3 and EU4.

In some embodiments, the carrier substrate SUB2 of the electronic device 200 may include an outer sidewall SW facing the encapsulation layer ML2 and connecting its upper surface and lower surface, wherein the width of the encapsulation layer ML2 disposed on the outer sidewall SW of the carrier substrate SUB2 is W1, the minimum width of the through hole TH in the second direction (e.g., direction D2) in the carrier substrate SUB2 is W2, and 2*W2≤W1≤10*W2. In this way, the encapsulation layer ML2 can meet the aforementioned requirement of protecting the carrier substrate SUB2, and can avoid problems caused by the shrinkage stress due to the width (W1 as shown in FIG. 4) of the encapsulation layer ML2 on the outer sidewall SW of the carrier substrate SUB2 is too large. In this embodiment, W1 and W2 shown in FIG. 4 may be, for example, dimensions measured in the horizontal direction (e.g., direction D2).

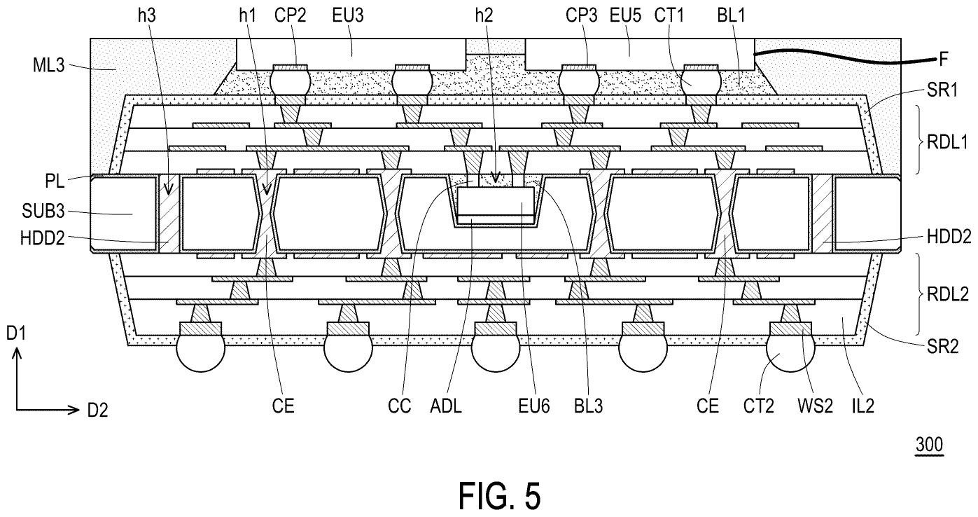

FIG. 5 is a cross-sectional schematic view of an electronic device according to yet another embodiment of the present disclosure. The electronic device 300 shown in FIG. 5 is similar to the electronic device 200 shown in FIG. 4. The main differences therebetween are relied on: the electronic device 300 includes electronic units EU3, EU5 and EU6 and a heat dissipation element HDD2; the redistribution structures RDL1 and RDL2 of the electronic device 300 are covered by the solder resist layers SR1 and SR2 respectively; and the carrier substrate SUB3 includes a through hole h1 provided with a conductive element CE, a blind hole h2 provided with an electronic unit EU6, and a through hole h3 provided with the heat dissipation element HDD2. Other identical or similar elements are represented by the same or similar reference numerals, and will not be repeated hereinafter.

As shown in FIG. 5, the electronic device 300 may include electronic units EU3 and EU5 disposed on the redistribution structure RDL1. The electronic units EU3 and EU5 may be electrically connected to the redistribution structure RDL1 through the connection members CT1. The electronic unit EU5 may include pads CP3. The electronic unit EU5 may be electrically connected to the connection members CT1 through the pads CP3. The pads CP3 may include any suitable conductive material, for example, copper (Cu), aluminum (Al), nickel (Ni), molybdenum (Mo), titanium (Ti), alloys or combinations of the above materials, or other suitable materials, but are not limited thereto. In some embodiments, the electronic unit EU5 may be a photonic integrated circuit (PIC) connected to a fiber F, but is not limited thereto.

In some embodiments, as shown in FIG. 5, the carrier substrate SUB3 of the electronic device 300 may include a through hole hl in which the aforementioned conductive element CE is formed, a blind hole h2 in which the electronic unit EU6 is disposed, and a through hole h3 in which the heat dissipation element HDD2 is formed. The electronic unit EU6 may include a surface mount device (SMD). In some embodiments, the electronic unit EU6 may include electronic components such as connectors. The electronic unit EU6 may be attached to the bottom surface of the blind hole h2 through an attachment ADL. The electronic unit EU6 may be electrically connected to the redistribution structure RDL1 through a connector CC. The buffer layer BL3 may be filled in the blind hole h2 to surround the electronic unit EU6. In this embodiment, “one element surrounding another element” may refer to the element being in contact with at least the side surface of the other element in the cross-sectional view. For example, as shown in FIG. 5, the buffer layer BL3 may be in contact with the side surface of the electronic unit EU6. The attachment ADL may include any suitable adhesive material, for example, epoxy resin, die attach film (DAF), other suitable adhesive materials, or combinations thereof, but is not limited thereto. The connector CC may include any suitable conductive material, for example, copper (Cu), aluminum (Al), nickel (Ni), molybdenum (Mo), titanium (Ti), alloys or combinations of the above materials, or other suitable materials, but is not limited thereto.

The heat dissipation element HDD2 may be formed in the through hole h3 of the carrier substrate SUB3 that is adjacent to the outer sidewall of the carrier substrate SUB3. The heat dissipation element HDD2 may be electrically floating, for example, the heat dissipation element HDD2 may not be electrically connected to the electronic unit EU3, electronic unit EU5, or electronic unit EU6. In this embodiment, the heat dissipation element HDD2 may be a conductive pillar formed in the through hole h3 of the carrier substrate SUB3. The heat dissipation element HDD2 may include any suitable conductive material.

In summary, in the electronic device of the embodiment of the present disclosure, the first seed layer among the plurality of seed layers includes the two neighboring sections in the through hole TH in which the two neighboring sections are spaced apart by the a gap in the first direction in the carrier substrate, and the ratio of the gap to the thickness of the carrier substrate is in a range of 0.01% to 0.1%. As such, the conductive element formed in the through hole TH can be well filled into the through hole TH, so that the defects caused by the high aspect ratio (for example, there may be a void existing in the conductive element having the high aspect ratio, and the void may cause a negative effect on the resistivity of the conductive element or may even cause a disconnection issue when the void is too large) can be improved, and therefore the reliability of the electronic device can be improved.

On the other hand, in the method for manufacturing the electronic device of the embodiment of the present disclosure, the first seed layer in the seed layer structure is formed to include the two neighboring sections in the through hole TH in which the two neighboring sections are spaced apart by a gap in the first direction in the carrier substrate. The method includes a step of determining the continuity of the seed layer structure in the through hole TH by measuring the gap. When the gap is greater than or equal to 0.1 μm, an auxiliary seed layer is provided between the two neighboring sections of the first seed layer before providing the conductive element in the through hole TH. As a result, the conductive element subsequently formed in the through hole TH can be well filled into the through hole TH, so that the aforementioned defects caused by the high aspect ratio can be improved, and therefore the reliability of the electronic device can be improved.

The above embodiments are used to describe the technical solution of the disclosure and are not a limitation thereof. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

Although the embodiments of the disclosure and their advantages are disclosed as above, it should be understood that any person with ordinary skill in the art, without departing from the spirit and scope of the disclosure, may make changes, substitutions, and modifications, and features between the embodiments may be mixed and replaced at will to form other new embodiments. In addition, the scope of the disclosure is not limited to the manufacturing processes, machines, manufactures, material compositions, devices, methods, and steps in the specific embodiments described in the specification. Any person with ordinary skill in the art may understand the current or future development processes, machines, manufactures, material compositions, devices, methods, and steps from the content of the disclosure, which may all be adopted according to the disclosure as long as they may implement substantially the same function or obtain substantially the same result in an embodiment described here. Therefore, the scope of the disclosure includes the above manufacturing processes, machines, manufactures, material compositions, devices, methods, and steps. In addition, each claim constitutes an individual embodiment, and the scope of the disclosure also includes the combination of each claim and embodiment. The scope of the disclosure shall be subject to the scope defined by the following claims.

What is claimed is:

1. An electronic device, comprising:
a carrier substrate having a first thickness in a first direction;
a through hole penetrating through the carrier substrate;
a seed layer structure disposed on the carrier substrate and extending into the through hole;
a conductive element disposed in the through hole; and
a circuit structure disposed on the conductive element,
wherein the seed layer structure comprises a plurality of seed layers, a first seed layer among the plurality of seed layers comprises two neighboring sections in the through hole, the two neighboring sections have a first gap in the first direction in the carrier substrate, and a ratio of the first gap to the first thickness is in a range of 0.01% to 0.1%.

2. The electronic device according to claim 1, wherein the carrier substrate comprises glass.

3. The electronic device according to claim 1, wherein the first thickness of the carrier substrate is in a range of 50 μm to 1000 μm.

4. The electronic device according to claim 1, further comprising:
a buffer layer disposed between the carrier substrate and the seed layer structure.

5. The electronic device according to claim 4, wherein a thickness of the buffer layer is ranging from about 0.01 μm to about 10 μm.

6. The electronic device according to claim 4, wherein a dissipation factor of the buffer layer is less than 0.01 at 10 GHz.

7. The electronic device according to claim 4, further comprising:
a spacer disposed between the carrier substrate and the buffer layer, wherein a thickness of the spacer is greater than a thickness of the buffer layer.

8. The electronic device according to claim 7, wherein a dissipation factor of the spacer is greater than a dissipation factor of the buffer layer.

9. The electronic device according to claim 7, wherein along a second direction perpendicular to the first direction, the spacer comprises a first side surface adjacent to the buffer layer and a second side surface away from the buffer layer, wherein a profile of the first side surface is different from a profile of the second side surface.

10. The electronic device according to claim 9, wherein an angle between an extension line of a sidewall of the through hole and the first direction is greater than or equal to an angle between an extension line of the first side surface of the spacer and the first direction.

11. The electronic device according to claim 1, wherein a sidewall of the through hole has a first roughness, an upper surface of the carrier substrate has a second roughness, and the first roughness is less than the second roughness.

12. The electronic device according to claim 1, wherein the plurality of seed layers comprise an auxiliary seed layer disposed between the two neighboring sections of the first seed layer.

13. The electronic device according to claim 1, further comprising:
an encapsulation layer surrounding the carrier substrate and an electronic unit,
wherein the carrier substrate comprises an outer sidewall in a second direction crossing the first direction, and the outer sidewall of the carrier substrate faces the encapsulation layer, a width of the encapsulation layer disposed on the outer sidewall of the carrier substrate is W1, a width of the through hole at a center in the first direction of the carrier substrate is W2, and 2*W2≤W1≤10*W2.

14. The electronic device according to claim 1, wherein an extension line of a sidewall of the through hole has an angle θ with the first direction, the angle θ is greater than or equal to 0 degree and less than or equal to 20 degrees.

15. The electronic device according to claim 1, wherein a second seed layer among the plurality of seed layers comprises two neighboring sections in the through hole, the two neighboring sections have a second gap in the first direction in the carrier substrate, and a ratio of the second gap to the first thickness is in a range of 0.01% to 0.1%.

16. The electronic device according to claim 15, wherein the plurality of seed layers comprise an auxiliary seed layer disposed between the two neighboring sections of the first seed layer, the auxiliary seed layer comprises a portion disposed between the first seed layer and the second seed layer in a second direction crossing the first direction.

17. The electronic device according to claim 16, wherein a thickness of the auxiliary seed layer in the second direction is less than a thickness of the first seed layer or a thickness of the second seed layer in the second direction.

18. The electronic device according to claim 1, further comprising:
an electronic unit disposed on the circuit structure and electrically connected to the conductive element through the circuit structure.

19. The electronic device according to claim 1, further comprising:
a blind hole disposed in the carrier substrate; and
an electronic unit disposed in the blind hole and electrically connected to the conductive element through the circuit structure.

20. A method for manufacturing an electronic device, comprising:
providing a carrier substrate;
forming a through hole in the carrier substrate;
providing a seed layer structure, wherein the seed layer structure is disposed on the carrier substrate and extends into the through hole, the seed layer structure comprises a first seed layer comprising two neighboring sections in the through hole, and the two neighboring sections have a first gap in a first direction in the carrier substrate; and
measuring the first gap to determine the continuity of the seed layer structure in the through hole, wherein:
when the first gap is less than 0.1 μm, providing a conductive element in the through hole; and
when the first gap is greater than or equal to 0.1 μm. providing an auxiliary seed layer between the two neighboring sections of the first seed layer before providing the conductive element in the through hole.
